(19) United States
(12) Patent Application Publication
(10) Pub. No.: US 2024/0038776 A1
(43) Pub. Date: Feb. 1, 2024

(54) DISPLAY SUBSTRATE AND DISPLAY DEVICE

(71) Applicants: BEIJING BOE DISPLAY TECHNOLOGY CO., LTD., Beijing (CN); BOE TECHNOLOGY GROUP CO., LTD., Beijing (CN)

(72) Inventors: Jingjing JIANG, (US); Xiaona LIU, (US); Yu MA, (US); Weitao CHEN, (US); Xibin SHAO, (US); Yan YAN, (US); Wei CAO, (US); Xiaoying LI, (US)

(21) Appl. No.: 17/753,365

(22) PCT Filed: Apr. 30, 2021
(86) PCT No.: PCT/CN2021/091406

§ 371 Date: Nov. 3, 2022

(51) Int. Cl. H01L 27/12

(52) U.S. Cl. CPC H01L 27/124

(57) ABSTRACT

The present disclosure provides a display substrate and a display device. The display substrate includes a middle display region, and first and second peripheral display regions arranged at two opposite sides of the middle display region respectively. Each pixel unit includes at least two sub-pixels in different colors and having a rectangular shape including long and short sides. In the middle display region and at least one of the first and second peripheral display regions, the sub-pixels in each pixel unit are sequentially arranged along a short side extension direction, extension directions of the first and second peripheral display regions are perpendicular to the short side extension direction in the middle display region, and the short side extension direction in at least one of the first and second peripheral display regions is perpendicular to the short side extension direction in the middle display region.

### TECHNICAL FIELD

The present disclosure relates to the field of display technology, in particular to a display substrate and a display device.

### BACKGROUND

In the related art, for a display product with a narrow frame, taking a spliced screen product as an example, some pixels at a periphery of a display panel may be shielded by a frame of a backlight module. Due to a difference in the straightness of edges of the frame, the pixels may be shielded to different extents, so Red, Green and Blue (RGB) sub-pixels of different pixels are adversely affected to different extents. At this time, rainbow-like patterns may occur at the edge of the screen, and different colors may occur at a left side and a right side of the screen.

### SUMMARY

An object of the present disclosure is to provide a display substrate and a display device, so as to prevent the occurrence of the rainbow-like patterns at the edge of the product with a narrow bezel, thereby to improve the quality of the product.

The present disclosure provides the following technical solutions.

In one aspect, the present disclosure provides in some embodiments a display substrate, including a middle display region, and a first peripheral display region and a second peripheral display region arranged at two opposite sides of the middle display region respectively. Each display region includes an array of pixel units, each pixel unit includes at least two sub-pixels emitting light in different colors, and an aperture of each sub-pixel is of a rectangular shape including a long side and a short side. In at least one of the first peripheral display region and the second peripheral display region and in the middle display region, the sub-pixels in each pixel unit are sequentially arranged along a short side extension direction of the sub-pixel, and an extension direction of the first peripheral display region and an extension direction of the second peripheral display region are perpendicular to a short side extension direction of the sub-pixel in the middle display region, and a short side extension direction of the sub-pixel in at least one of the first peripheral display region and the second peripheral display region is perpendicular to the short side extension direction of the sub-pixel in the middle display region.

In a possible embodiment of the present disclosure, the pixel unit at least includes a first sub-pixel, a second sub-pixel and a third sub-pixel, a pixel aperture area of the first sub-pixel in the middle display region is the same as a pixel aperture area of the first sub-pixel in the first peripheral display region and the second peripheral display region, a pixel aperture area of the second sub-pixel in the middle display region is the same as a pixel aperture area of the second sub-pixel in the first peripheral display region and the second peripheral display region; and a pixel aperture area of the third sub-pixel in the middle display region is the same as a pixel aperture area of the third sub-pixel in the first peripheral display region and the second peripheral display region.

In a possible embodiment of the present disclosure, the display substrate further includes data lines and gate lines crossing and insulated from the data lines, each sub-pixel is provided with a thin film transistor and a pixel electrode, a gate electrode of the thin film transistor is coupled to a corresponding gate line, a source electrode of the thin film transistor is coupled to a corresponding data line, and a drain electrode of the thin film transistor is coupled to the pixel electrode. In a plurality of pixel units in a same row, the source electrodes of the thin film transistors of the sub-pixels in different colors are coupled to different data lines, the gate electrode of the thin film transistor of each sub-pixel is coupled to a same gate line adjacent to the pixel units in the row, or coupled to at least two gate lines adjacent to the pixel units in the row, and the gate electrodes of the thin film transistors of the sub-pixels in a same color are coupled to a same gate line.

In a possible embodiment of the present disclosure, in at least one of the first peripheral display region and the second peripheral display region, at least one gate line branch is further arranged on and cross-coupled to each gate line, and the source electrode of the thin film transistor of the sub-pixel in at least one color in the pixel unit is coupled to the gate line branch.

In a possible embodiment of the present disclosure, when the gate electrode of each sub-pixel in the pixel units in the same row is coupled to a same gate line adjacent to the pixel units in the row, in the first peripheral display region and the second peripheral display region, at least one gate line branch is further arranged on and cross-coupled to the gate line, the gate electrode of the thin film transistor of one sub-pixel closest to the gate line in the pixel unit is coupled to the gate line, and the gate electrode of the thin film transistor of the sub-pixel away from the gate line in the pixel unit is coupled to the gate line branch.

In a possible embodiment of the present disclosure, when the gate electrodes of the sub-pixels in the pixel units in a same row are coupled to at least two gate lines adjacent to the pixel units in the row, in the first peripheral display region and the second peripheral display region, one of the at least two gate lines adjacent to the pixel units in the row is a first gate line, and the other gate line is a second gate line. At least one first gate line branch is arranged on and cross-coupled to the first gate line, or at least one second gate line branch is arranged on and cross-coupled to the second gate line. The gate electrode of the thin film transistor of one sub-pixel closest to the first gate line in the pixel unit is coupled to the first gate line, the gate electrode of the thin film transistor of one sub-pixel closest to the second gate line in the pixel unit is coupled to the second gate line, and the gate electrode of the thin film transistor of the sub-pixel away from the first gate line and the second gate line in the pixel unit is coupled to the first gate line branch or the second gate line branch.

In a possible embodiment of the present disclosure, in the first peripheral display region and the second peripheral display region, the sub-pixels in a same color in the pixel units in a same column are coupled to a same data line, and each data line perpendicularly crosses the gate line or is arranged in such a manner as to bypass the sub-pixel.

In another aspect, the present disclosure provides in some embodiments a display substrate, including the above-mentioned display substrate.

In a possible embodiment of the present disclosure, the display device includes a spliced screen including a plurality of single screens spliced with each other, each single screen includes the display substrate and a protective cover plate, a light shielding layer is arranged on the protective cover plate and extends along a side edge of the protective cover plate, a part of the peripheral display region is shielded by the light shielding layer, and the other part of the peripheral display region is not shielded by the light shielding layer.

In a possible embodiment of the present disclosure, the array of pixel units in each single screen is aligned with the array of pixel units in an adjacent single screen.

The present disclosure has the following beneficial effects.

According to the display substrate and the display device in the embodiments of the present disclosure, an arrangement structure of the pixels is improved. To be specific, the sub-pixels in the pixel units in the middle display region are sequentially arranged along the short side extension direction of the sub-pixel, the sub-pixels in the pixel units in at least one of the two peripheral display regions extending in a direction perpendicular to the short side extension direction of the sub-pixel in the middle display region (i.e., the first peripheral display region and the second peripheral display region) are sequentially arranged along the short side extension direction, and an extension direction of the short side of the sub-pixel in at least one of the first peripheral display region and the second peripheral display region is perpendicular to an extension direction of the short side of the sub-pixel in the middle display region. When the display substrate is applied to a structure with a narrow frame and the pixel units in the first peripheral display region and/or the second peripheral display region are shielded by the frame, a part of the pixel units in the first peripheral display region and the second peripheral display region are shielded by the frame, the other part of the pixel units are not shielded by the frame, the apertures of the sub-pixel in the first peripheral display region and the second peripheral display region are adversely affected at a same proportion. As a result, it is able to prevent the occurrence of rainbow-like patterns, thereby to improve the quality of the product.

### BRIEF DESCRIPTION OF THE DRAWINGS

FIG. 1 is a sectional view of a spliced screen product in the related art;

FIG. 2 is a schematic view showing a situation where a part of peripheral subpixels are shielded by a frame of the spliced screen in FIG. 1, with merely a part of the spliced screen at one corner being shown;

FIG. 3 is a schematic view showing an arrangement structure of pixels in a display substrate according to one embodiment of the present disclosure;

FIG. 4 is a schematic view showing a wiring mode of the display substrate at C in FIG. 3 according to one embodiment of the present disclosure;

FIG. 5 is another schematic view showing the wiring mode of the display substrate at C in FIG. 3 according to one embodiment of the present disclosure;

FIG. 6 is yet another schematic view showing the wiring mode of the display substrate at C in FIG. 3 according to one embodiment of the present disclosure;

FIG. 7 is still yet another schematic view showing the wiring mode of the display substrate at C in FIG. 3 according to one embodiment of the present disclosure; and

FIG. 8 is still yet another schematic view showing the wiring mode of the display substrate at C in FIG. 3 according to one embodiment of the present disclosure.

### DETAILED DESCRIPTION

In order to make the objects, the technical solutions and the advantages of the present disclosure more apparent, the present disclosure will be described hereinafter in a clear and complete manner in conjunction with the drawings and embodiments. Obviously, the following embodiments merely relate to a part of, rather than all of, the embodiments of the present disclosure, and based on these embodiments, a person skilled in the art may, without any creative effort, obtain the other embodiments, which also fall within the scope of the present disclosure.

Unless otherwise defined, any technical or scientific term used herein shall have the common meaning understood by a person of ordinary skills. Such words as “first” and “second” used in the specification and claims are merely used to differentiate different components rather than to represent any order, number or importance. Similarly, such words as “one” or “one of” are merely used to represent the existence of at least one member, rather than to limit the number thereof. Such words as “include” or “including” intends to indicate that an element or object before the word contains an element or object or equivalents thereof listed after the word, without excluding any other element or object. Such words as “connect/connected to” or “couple/coupled to” may include electrical connection, direct or indirect, rather than to be limited to physical or mechanical connection. Such words as “on”, “under”, “left” and “right” are merely used to represent relative position relationship, and when an absolute position of the object is changed, the relative position relationship will be changed too.

Some descriptions in the related art will be given hereinafter at first.

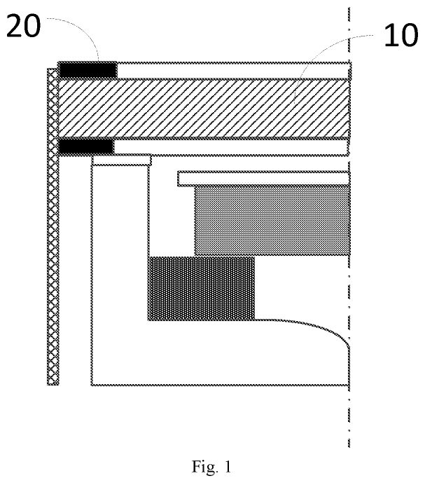

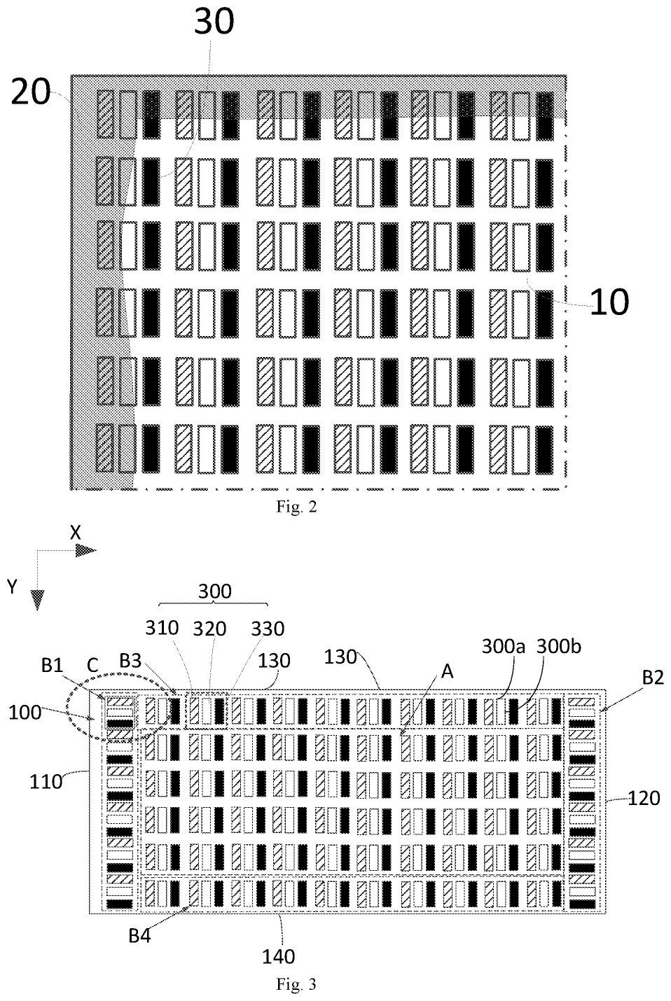

In the related art, for a display product with a narrow frame, taking a spliced screen as an example, FIG. 1 is a sectional view of a spliced screen product in the related art, and FIG. 2 is a schematic view showing a situation where a part of peripheral pixels are shielded by the frame of the spliced screen in FIG. 1, with merely a part of the spliced screen at a corner being shown. As shown in FIG. 1 and FIG. 2, some pixels at a periphery of a display substrate 10 are shielded by a frame 20. Due to a difference in the straightness of edges of the frame, the pixels may be shielded to different extents, so RGB sub-pixels 30 in different pixel units are adversely affected to different extents. At this time, rainbow-like patterns may occur at the edge of the screen, and different colors may occur at two opposite sides of the screen.

An object of the present disclosure is to provide a display substrate and a display device, so as to prevent the occurrence of the rainbow-like patterns in the display products through improving an arrangement structure of the pixels, thereby to improve the product quality.

FIG. 3 is a schematic view showing an arrangement structure of pixels in a display substrate according to one embodiment of the present disclosure. As shown in FIG. 3, the display substrate includes a middle display region A, and a first peripheral display region B1 and a second peripheral display region B2 arranged at two opposite sides of the middle display region A respectively. Each display region includes an array of pixel units including a plurality of pixel units 300 arranged in an array form, each pixel unit 300 includes at least two sub-pixels emitting light in different colors, an aperture of each sub-pixel is of a rectangular shape having a long side 300a and a short side 300b. In at least one of the first peripheral display region B1 and the second peripheral display region B2 and in the middle display region A, the sub-pixels in each pixel unit 300 are sequentially arranged along a short side extension direction of the sub-pixel, an extension direction of the first peripheral display region B1 and an extension direction of the second peripheral display region B2 are perpendicular to a short side extension direction of the sub-pixel in the middle display region A, and a short side extension direction of the sub-pixel in at least one of the first peripheral display region B1 and the second peripheral display region B2 is perpendicular to the short side extension direction of the sub-pixel in the middle display region A.

As shown in FIG. 3, the short side extension direction of each sub-pixel in the middle display region A is a row direction X of the array of pixel units, and a long side extension direction is a column direction Y of the array of pixel units. The first peripheral display region B1 is a peripheral display region arranged on the left of the middle display region A, and the second peripheral display region B2 is a peripheral display region arranged on the right of the middle display region A. The sub-pixels in each pixel unit 300 in the middle display region A are sequentially arranged along the short side extension direction, i.e., the direction X. The short side extension direction of each sub-pixel of the pixel units 300 in the first peripheral display region B1 and the second peripheral display region B2, i.e., the direction Y, is perpendicular to the short side extension direction of the sub-pixel in the middle display region, and the sub-pixels in the pixel units are sequentially arranged along the short side extension direction, i.e., the direction Y.

When the display substrate in the embodiments of the present disclosure is applied to a display product with a narrow frame, in particular to a spliced screen, the first peripheral display region B1 and the second peripheral display region B2 may be partially shielded by four sides of the frame.

According to the embodiments of the present disclosure, an arrangement structure of the pixels on the display substrate is improved. To be specific, the sub-pixels in the pixel units 300 in the middle display region A are sequentially arranged along the short side extension direction of the sub-pixel, the sub-pixels in the pixel units 300 in at least one of the two peripheral display regions extending in a direction perpendicular to the short side extension direction of the sub-pixel in the middle display region (i.e., the first peripheral display region B1 and the second peripheral display region B2) are sequentially arranged along the short side extension direction, and an extension direction of the short side of the sub-pixel in at least one of the first peripheral display region B1 and the second peripheral display region B2 is perpendicular to an extension direction of the short side of the sub-pixel in the middle display region A. When the display substrate is applied to a structure with a narrow frame, edges of the frame at a first side 110 and a second side 120 may extend in a same direction as an arrangement direction of the sub-pixels in each pixel unit 300 in the first peripheral display region B1 and teh second peripheral display region B2. When the pixel units 300 in the first peripheral display region B1 and/or the second peripheral display region B2 are shielded by the frame, a part of the pixel units 300 in the first peripheral display region B1 and the second peripheral display region B2 are shielded by the frame, the other part of the pixel units are not shielded by the frame, and the apertures of the sub-pixel in the first peripheral display region and the second peripheral display region are adversely affected at a same proportion. As a result, it is able to prevent the occurrence of rainbow-like patterns, thereby to improve the quality of the product.

It should be appreciated that, as shown in FIG. 3, the first peripheral display region B1 may include only one row of pixel units 300 or at least two rows of pixel units 300, and the second peripheral display region B2 may include one row of pixel units or at least two rows of pixel units 300.

In some embodiments of the present disclosure, the pixel unit 300 at least includes a first sub-pixel 310, a second sub-pixel 320 and a third sub-pixel 330. For example, the first sub-pixel 310 is a red sub-pixel, the second sub-pixel 320 is a green sub-pixel, and the third sub-pixel 330 is a blue sub-pixel.

As shown in FIG. 3, a pixel aperture area of the first sub-pixel 310 in the middle display region A is the same as a pixel aperture area of the first sub-pixel 310 in the first peripheral display region B1 and the second peripheral display region B2, a pixel aperture area of the second sub-pixel 320 in the middle display region A is the same as a pixel aperture area of the second sub-pixel 320 in the first peripheral display region B1 and the second peripheral display region B2, and a pixel aperture area of the third sub-pixel 330 in the middle display region A is the same as a pixel aperture area of the third sub-pixel 330 in the first peripheral display region B1 and the second peripheral display region B2.

In the embodiments of the present disclosure, for the sub-pixels in a same color, the aperture area of the sub-pixel in each of the first peripheral display region B1 and the second peripheral display region B2 is the same as the aperture area of the sub-pixel in the middle display region A.

In order to achieve the arrangement structure of pixels in the display substrate in the embodiments of the present disclosure, there are various wiring modes for a display driving circuitry in the display substrate in the embodiments of the present disclosure.

In the embodiments of the present disclosure, the base substrate 100 includes data lines 500 and gate lines 600 crossing and insulated from the data lines 500. Each sub-pixel is provided with a thin film transistor and a pixel electrode, a gate electrode of the thin film transistor is coupled to a corresponding gate line 600, a source electrode of the thin film transistor is coupled to a corresponding data line 500, and a drain electrode of the thin film transistor is coupled to the pixel electrode. In a plurality of pixel units 300 in a same row, the source electrodes of the thin film transistors of the sub-pixels in different colors are coupled to different data lines 500, and the gate electrodes of the thin film transistors of the sub-pixels are coupled to a same gate line 600 adjacent to the pixel units 300 in the row, or coupled to at least two gate lines 600 adjacent to the pixel units 300, and the gate electrodes of the thin film transistors of the sub-pixels in a same color are coupled to a same gate line 600.

The arrangement direction of the sub-pixels in the pixel units 300 in the first peripheral display region B1 and the second peripheral display region B2 is different from the arrangement direction of the sub-pixels in the pixel units 300 in the middle display region A. Hence, for the pixel units 300 in a same row, a wiring mode of the signal lines in the first peripheral display region B1 and the second peripheral display region B2 is different from that in the middle display region A.

In the middle display region A, the sub-pixels of the pixel units 300 are sequentially arranged along the short side extension direction of the sub-pixels, i.e., direction X, and the gate line 600 extends along direction X. Hence, distances between the thin film transistors of the sub-pixels and the gate line 600 are the same, and the source electrode of each thin film transistor may be directly coupled to the gate line 600. In the pixel units 300 in the first peripheral display region B1 and the second peripheral display region B2, the sub-pixels are sequentially arranged along the direction perpendicular to the short sides of the sub-pixels in the middle display region, i.e., direction Y. Hence, distances between the sub-pixels in a same pixel unit 300 and the gate line 600 are different. In order to enable the sub-pixels in the same pixel unit 300 to be coupled to a same or at least two gate lines 600 adjacent to the pixel unit 300, in at least one of the first peripheral display region B1 and the second peripheral display region B2, at least one gate line branch 600′ is further arranged on and cross-coupled to the gate line 600, an extension direction of the gate line branch 600′ is a long side extension direction of the sub-pixel in the middle display region, that is, direction Y, and the gate line branch 600′ may be formed through extending the gate line 600. The source electrode of the thin film transistor of the sub-pixel in at least one color in the pixel unit 300 is coupled to the gate line 600 through the gate line branch 600′.

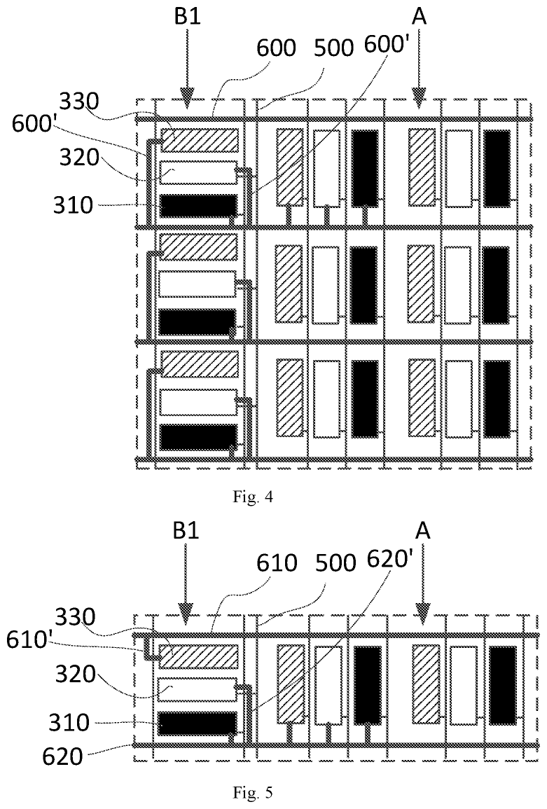

In a possible embodiment of the present disclosure, as shown in FIG. 4, when the gate electrodes of the sub-pixels in the pixel units 300 in the same row are coupled to the same gate line 600 adjacent to the pixel units 300 in the row, in the first peripheral display region B1 and the second peripheral display region B2, at least one gate line branch 600′ is further arranged on and cross-coupled to the gate line 600, the gate electrode of the thin film transistor of one sub-pixel closest to the gate line 600 in the pixel unit 300 is coupled to the gate line 600, and the gate electrode of the thin film transistor of the sub-pixel away from the gate line 600 in the pixel unit is coupled to the gate line branch 600′.

For example, taking the display substrate in FIG. 4 as an example, the pixel unit 300 includes a first sub-pixel 310, a second sub-pixel 320, and a third sub-pixel 330. The thin film transistors of the pixel units 300 in a same row are all coupled to a same gate line 600 arranged at one side of the pixel units 300 in the row close to a fourth side 140 (i.e., the gate line 600 below the pixel unit 300 as shown in FIG. 4). In the first peripheral display region B1 and the second peripheral display region B2, the first sub-pixel 310 of the pixel unit 300 is arranged on a side closest to the fourth side 140, the third sub-pixel 330 is arranged on a side closest to a third side 130, and two gate line branches 600′ are arranged on the gate line 600. The thin film transistor of the first sub-pixel 310 is directly coupled to the gate line 600, and the thin film transistor of the second sub-pixel 320 is coupled to the gate line 600 through one of the two gate line branches 600′, and the thin film transistor of the third sub-pixel 330 is coupled to the gate line 600 through the other gate line branch 600′ of the two gate line branches 600′.

In a possible embodiment of the present disclosure, as shown in FIG. 5, when the gate electrodes of the sub-pixels in the pixel units 300 in the same row are coupled to at least two gate lines 600 adjacent to the pixel units 300 in the row, in the first peripheral display region B1 and the second peripheral display region B2, one of the at least two gate lines 600 adjacent to the pixel units 300 in the row is a first gate line 610, and the other gate line 600 is a second gate line 620. At least one first gate line branch 610′ is arranged on and cross-coupled to the first gate line 610, or at least one second gate line branch 620′ is arranged on and cross-coupled to the second gate line 620. The gate electrode of the thin film transistor of one sub-pixel closest to the first gate line 610 in the pixel unit 300 is coupled to the first gate line 610, the gate electrode of the thin film transistor of one sub-pixel closest to the second gate line 620 in the pixel unit 300 is coupled to the second gate line 620, and the gate electrode of the thin film transistor of the sub-pixel away from the first gate line 610 and the second gate line 620 in the pixel unit 300 is coupled to the first gate line branch 610′ or the second gate line branch 620′.

For example, taking the display substrate in FIG. 5 as an example, the pixel unit 300 includes a first sub-pixel 310, a second sub-pixel 320, and a third sub-pixel 330. The thin film transistors of the pixel units 300 in a same row are all coupled to the first gate line 610 or the second gate line 620 adjacent to the pixel units 300 in the same row (i.e., the two gate lines 600 above and below the pixel unit 300 as shown in FIG. 5). In the first peripheral display region B1 and the second peripheral display region B2, the first sub-pixel 310 of the pixel unit 300 is arranged on a side closest to the fourth side 140, and the third sub-pixel 330 is arranged on a side closest to the third side 130. The first sub-pixel 310 is directly coupled to the first gate line 610 or coupled to the first gate line 610 through a first gate line branch 610′, the third sub-pixel 330 is directly coupled to a second gate line 620 or coupled to the second gate line 620 through a second gate line branch 620′, and the second sub-pixel 320 is coupled to another first gate line branch 610′ on the first gate line 610 or another second gate line branch 620′ on the second gate line 620.

In addition, in a possible embodiment of the disclosure, as shown in FIG. 4, in the middle display region A, the sub-pixels in different colors are coupled to different data lines 500, and the sub-pixels in a same color in a same column in the pixel units 300 are coupled to a same data line 500.

In the first peripheral display region B1 and the second peripheral display region B2, the sub-pixels in a same color in the pixel units 300 in a same column are coupled to a same data line 500, and each data line 500 is perpendicularly cross-coupled to the gate line 600 or is arranged in such a manner as to bypass the sub-pixel.

As shown in FIG. 4, in the first peripheral display region B1 and the second peripheral display region B2, the sub-pixels in different colors in a same pixel unit 300 are coupled to different data lines 500, and the data lines 500 are perpendicular to the gate lines 600. The data lines 500 should be arranged in such a manner that the data lines 500 do not overlap each other.

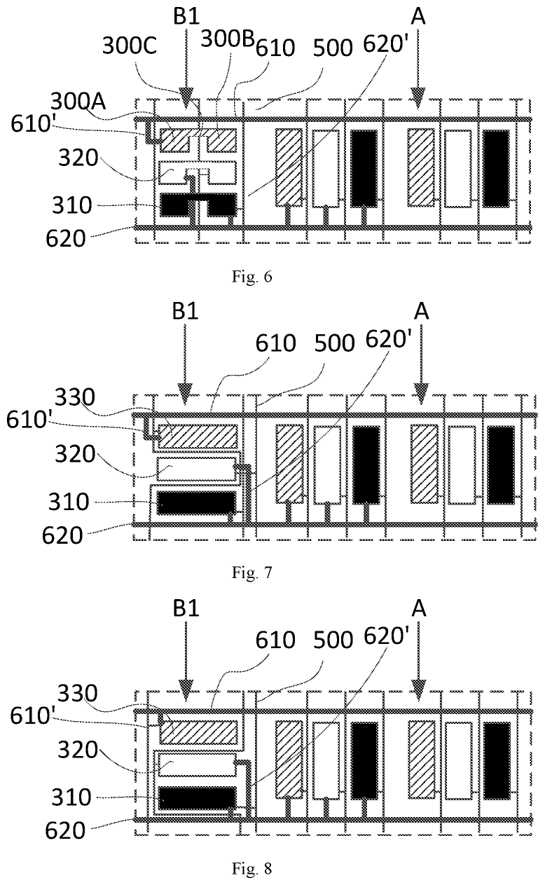

In a possible embodiment of the present disclosure, as shown in FIG. 6, in the first peripheral display region B1 and the second peripheral display region B2, a first data line 500 coupled to the first sub-pixel 310 and a third data line 500 coupled to the third sub-pixel 330 in the pixel unit 300 are arranged at two opposite sides of the pixel unit 300 respectively, i.e., a side close to the middle display region A and a side away from the middle display region A. A second data line 500 coupled to the second sub-pixel 320 is arranged in the middle of the pixel unit 300, and the pixel electrode of each sub-pixel includes a first portion 300A and a second portion 300B. The first portion 300A and the second portion 300B are coupled to each other through a coupling bridge 300C, and an orthogonal projection of the first portion onto the base substrate 100 and an orthogonal projection of the second portion onto the base substrate 100 do not overlap an orthogonal projection of the second data line 500 onto the base substrate 100, so as to reduce a parasitic capacitance.

In another possible embodiment of the present disclosure, as shown in FIG. 5, in the first peripheral display region B1 and the second peripheral display region B2, a first data line 500 coupled to the first sub-pixel 310 and a third data line 500 coupled to the third sub-pixel 330 in the pixel unit 300 are arranged at two opposite sides of the pixel unit 300 respectively, i.e., a side close to the middle display region A and a side away from the middle display region A. A second data line 500 coupled to the second sub-pixel 320 is arranged at a side of the pixel unit 300 close to the middle display region A or away from the middle display region A.

In yet another possible embodiment of the present disclosure, as shown in FIG. 7, in the first peripheral display region B1 and the second peripheral display region B2, a first data line 500 coupled to the first sub-pixel 310 and a second data line 500 coupled to the second sub-pixel 320 in the pixel unit 300 are arranged at two opposite sides of the pixel unit 300 respectively or at a same side of the pixel unit, and arranged perpendicular to the gate line 600. A third data line 500 coupled to the third sub-pixel 330 is arranged in such a manner as to bypass the third sub-pixel 330.

In still yet another possible embodiment of the present disclosure, as shown in FIG. 8, in the first peripheral display region B1 and the second peripheral display region B2, a first data line 500 coupled to the first sub-pixel 310 and a third data line 500 coupled to the third sub-pixel 330 in the pixel unit 300 are arranged at two opposite sides of the pixel unit 300 respectively, and arranged perpendicular to the gate line 600. A second data line 500 coupled to the second sub-pixel 320 is arranged in such a manner as to bypass the second sub-pixel 320.

In still yet another possible embodiment of the present disclosure, as shown in FIG. 8, in the first peripheral display region B1 and the second peripheral display region B2, a second data line 500 coupled to the second sub-pixel 320 and a third data line 500 coupled to the third sub-pixel 330 in the pixel unit 300 are arranged at a same side of the pixel unit 300 or at two opposite sides of the pixel unit 300, and arranged perpendicular to the gate line 600. A first data line 500 coupled to the first sub-pixel 310 is arranged in such a manner as to bypass the first sub-pixel 310.

It should be appreciated that, the above description about the wiring modes of the gate lines 600 and the data lines 500 are for illustrative purposes only, and the present disclosure shall not be limited thereto.

The present disclosure further provides in some embodiments a display device, including the above-mentioned display substrate. The display device may be a computer, a mobile phone, a television, etc.

In a possible embodiment of the present disclosure, the display device includes a spliced screen including a plurality of single screens spliced with each other, each single screen includes the display substrate and a protective cover plate, a light shielding layer is arranged on the protective cover plate and extends along a side edge of the protective cover plate, a part of the peripheral display region is shielded by the light shielding layer, and the other part of the peripheral display region is not shielded by the light shielding layer.

It should be appreciated that, the array of pixel units in each single screen is aligned with the array of pixel units in an adjacent single screen. That is, when a plurality of single screens is spliced in direction X (i.e., the short side extension direction of the sub-pixels in the middle display region), an N^{th} row of pixel units of each single screen is arranged on a same straight line, and identically, when a plurality of single screens is spliced in direction Y (i.e., the direction vertical to the short sides of the sub-pixels in the middle display region), an N^{th} column of pixel units of each single screen is arranged on a same straight line.

Some description will be given as follows.

(1) The drawings merely relate to structures involved in the embodiments of the present disclosure, and the other structures may refer to those known in the art.

(2) For clarification, in the drawings for describing the embodiments of the present disclosure, a thickness of a layer or region is zoomed out or in, i.e., these drawings are not provided in accordance with an actual scale. It should be appreciated that, in the case that such an element as layer, film, region or substrate is arranged “on” or “under” another element, it may be directly arranged “on” or “under” the other element, or an intermediate element may be arranged therebetween.

(3) In the case of no conflict, the embodiments of the present disclosure and the features therein may be combined to acquire new embodiments.

The above embodiments are for illustrative purposes only, but the present disclosure is not limited thereto. Obviously, a person skilled in the art may make further modifications and improvements without departing from the spirit of the present disclosure, and these modifications and improvements shall also fall within the scope of the present disclosure.

1. A display substrate, comprising a middle display region, and a first peripheral display region and a second peripheral display region arranged at two opposite sides of the middle display region respectively, wherein each display region comprises an array of pixel units, each pixel unit comprises at least two sub-pixels emitting light in different colors, and an aperture of each sub-pixel is of a rectangular shape comprising a long side and a short side;
wherein in at least one of the first peripheral display region and the second peripheral display region and in the middle display region, the sub-pixels in each pixel unit are sequentially arranged along a short side extension direction of the sub-pixel, an extension direction of the first peripheral display region and an extension direction of the second peripheral display region are perpendicular to a short side extension direction of the sub-pixel in the middle display region, and a short side extension direction of the sub-pixel in at least one of the first peripheral display region and the second peripheral display region is perpendicular to the short side extension direction of the sub-pixel in the middle display region.

2. The display substrate according to claim 1, wherein the pixel unit at least comprises a first sub-pixel, a second sub-pixel and a third sub-pixel, a pixel aperture area of the first sub-pixel in the middle display region is the same as a pixel aperture area of the first sub-pixel in the first peripheral display region and the second peripheral display region, a pixel aperture area of the second sub-pixel in the middle display region is the same as a pixel aperture area of the second sub-pixel in the first peripheral display region and the second peripheral display region, and a pixel aperture area of the third sub-pixel in the middle display region is the same as a pixel aperture area of the third sub-pixel in the first peripheral display region and the second peripheral display region.

3. The display substrate according to claim 1, further comprising data lines and gate lines crossing and insulated from the data lines, wherein each sub-pixel is provided with a thin film transistor and a pixel electrode, a gate electrode of the thin film transistor is coupled to a corresponding gate line, a source electrode of the thin film transistor is coupled to a corresponding data line, and a drain electrode of the thin film transistor is coupled to the pixel electrode; and
in a plurality of pixel units in a same row, the source electrodes of the thin film transistors of the sub-pixels in different colors are coupled to different data lines, the gate electrode of the thin film transistor of each sub-pixel is coupled to a same gate line adjacent to the pixel units in the row, or coupled to at least two gate lines adjacent to the pixel units in the row, and the gate electrodes of the thin film transistors of the sub-pixels in a same color are coupled to a same gate line.

4. The display substrate according to claim 3, wherein in at least one of the first peripheral display region and the second peripheral display region, at least one gate line branch is further arranged on and cross-coupled to each gate line, and the source electrode of the thin film transistor of the sub-pixel in at least one color in the pixel unit is coupled to the gate line branch.

5. The display substrate according to claim 4, wherein when the gate electrode of each sub-pixel in the pixel units in the same row is coupled to a same gate line adjacent to the pixel units in the row, in the first peripheral display region and the second peripheral display region, at least one gate line branch is further arranged on and cross-coupled to the gate line, the gate electrode of the thin film transistor of one sub-pixel closest to the gate line in the pixel unit is coupled to the gate line, and the gate electrode of the thin film transistor of the sub-pixel away from the gate line in the pixel unit is coupled to the gate line branch.

6. The display substrate according to claim 5, wherein when the gate electrodes of the sub-pixels in the pixel units in a same row are coupled to at least two gate lines adjacent to the pixel units in the row, in the first peripheral display region and the second peripheral display region, one of the at least two gate lines adjacent to the pixel units in the row is a first gate line, and the other gate line is a second gate line;
at least one first gate line branch is arranged on and cross-coupled to the first gate line, or at least one second gate line branch is arranged on and cross-coupled to the second gate line; and
the gate electrode of the thin film transistor of one sub-pixel closest to the first gate line in the pixel unit is coupled to the first gate line, the gate electrode of the thin film transistor of one sub-pixel closest to the second gate line in the pixel unit is coupled to the second gate line, and the gate electrode of the thin film transistor of the sub-pixel away from the first gate line and the second gate line in the pixel unit is coupled to the first gate line branch or the second gate line branch.

7. The display substrate according to claim 3, wherein in the first peripheral display region and the second peripheral display region, the sub-pixels in a same color in the pixel units in a same column are coupled to a same data line, and each data line perpendicularly crosses the gate line or is arranged in such a manner as to bypass the sub-pixel.

8. A display device, comprising the display substrate according to any one of claim 1.

9. The display device according to claim 8, wherein the display device comprises a spliced screen comprising a plurality of single screens spliced with each other, each single screen comprises the display substrate and a protective cover plate, a light shielding layer is arranged on the protective cover plate and extends along a side edge of the protective cover plate, a part of the peripheral display region is shielded by the light shielding layer, and the other part of the peripheral display region is not shielded by the light shielding layer.

10. The display device according to claim 9, wherein the array of pixel units in each single screen is aligned with the array of pixel units in an adjacent single screen.

11. The display device according to claim 8, wherein the pixel unit at least comprises a first sub-pixel, a second sub-pixel and a third sub-pixel, a pixel aperture area of the first sub-pixel in the middle display region is the same as a pixel aperture area of the first sub-pixel in the first peripheral display region and the second peripheral display region, a pixel aperture area of the second sub-pixel in the middle display region is the same as a pixel aperture area of the second sub-pixel in the first peripheral display region and the second peripheral display region, and a pixel aperture area of the third sub-pixel in the middle display region is the same as a pixel aperture area of the third sub-pixel in the first peripheral display region and the second peripheral display region.

12. The display device according to claim 8, further comprising data lines and gate lines crossing and insulated from the data lines, wherein each sub-pixel is provided with a thin film transistor and a pixel electrode, a gate electrode of the thin film transistor is coupled to a corresponding gate line, a source electrode of the thin film transistor is coupled to a corresponding data line, and a drain electrode of the thin film transistor is coupled to the pixel electrode; and
in a plurality of pixel units in a same row, the source electrodes of the thin film transistors of the sub-pixels in different colors are coupled to different data lines, the gate electrode of the thin film transistor of each sub-pixel is coupled to a same gate line adjacent to the pixel units in the row, or coupled to at least two gate lines adjacent to the pixel units in the row, and the gate electrodes of the thin film transistors of the sub-pixels in a same color are coupled to a same gate line.

13. The display device according to claim 12, wherein in at least one of the first peripheral display region and the second peripheral display region, at least one gate line branch is further arranged on and cross-coupled to each gate line, and the source electrode of the thin film transistor of the sub-pixel in at least one color in the pixel unit is coupled to the gate line branch.

14. The display device according to claim 13, wherein when the gate electrode of each sub-pixel in the pixel units in the same row is coupled to a same gate line adjacent to the pixel units in the row, in the first peripheral display region and the second peripheral display region, at least one gate line branch is further arranged on and cross-coupled to the gate line, the gate electrode of the thin film transistor of one sub-pixel closest to the gate line in the pixel unit is coupled to the gate line, and the gate electrode of the thin film transistor of the sub-pixel away from the gate line in the pixel unit is coupled to the gate line branch.

15. The display device according to claim 14, wherein when the gate electrodes of the sub-pixels in the pixel units in a same row are coupled to at least two gate lines adjacent to the pixel units in the row, in the first peripheral display region and the second peripheral display region, one of the at least two gate lines adjacent to the pixel units in the row is a first gate line, and the other gate line is a second gate line;
at least one first gate line branch is arranged on and cross-coupled to the first gate line, or at least one second gate line branch is arranged on and cross-coupled to the second gate line; and
the gate electrode of the thin film transistor of one sub-pixel closest to the first gate line in the pixel unit is coupled to the first gate line, the gate electrode of the thin film transistor of one sub-pixel closest to the second gate line in the pixel unit is coupled to the second gate line, and the gate electrode of the thin film transistor of the sub-pixel away from the first gate line and the second gate line in the pixel unit is coupled to the first gate line branch or the second gate line branch.

16. The display device according to claim 12, wherein in the first peripheral display region and the second peripheral display region, the sub-pixels in a same color in the pixel units in a same column are coupled to a same data line, and each data line perpendicularly crosses the gate line or is arranged in such a manner as to bypass the sub-pixel.
